(19) United States
(12) Patent Application Publication
(10) Pub. No.: US 2023/0178491 A1
(43) Pub. Date: Jun. 8, 2023

(54) SEMICONDUCTOR DEVICE

(71) Applicant: KIOXIA CORPORATION, Tokyo (JP)

(72) Inventors: Yasuo TAKEMOTO, Kamakura Kanagawa (JP); Hitoshi ISHII, Chigasaki Kanagawa (JP); Masayuki MIURA, Ota Tokyo (JP)

(73) Assignee: KIOXIA CORPORATION, Tokyo (JP)

(21) Appl. No.: 17/895,377

(22) Filed: Aug. 25, 2022

(30) Foreign Application Priority Data
Dec. 8, 2021 (JP) 2021-199458

(51) Int. Cl. H01L 23/538; H01L 23/528; H01L 23/00; H01L 23/498; H01L 23/31; H01L 25/065

(52) U.S. Cl. CPC H01L 23/5386; H01L 23/5384; H01L 23/528; H01L 23/562; H01L 23/49816; H01L 23/3121; H01L 24/05; H01L 25/0657; H01L 24/16; H01L 2224/05541; H01L 2224/16151

(57) ABSTRACT

A semiconductor device includes: a printed wiring substrate; a semiconductor chip mounted on a first surface of the printed wiring substrate; a sealing resin sealing the semiconductor chip on the first surface of the printed wiring substrate; an electrode pad provided on a second surface on a side opposite to the first surface of the printed wiring substrate; an electrode terminal connected to the electrode pad and protruding from the second surface; and a metal layer provided on a surface of the electrode pad on the electrode terminal side or on the side opposite to the electrode terminal so as to straddle a boundary line of the bonding surface between the electrode terminal and the electrode pad which is at least a boundary line on a side facing an outside of a mounting region of the semiconductor chip.

### CROSS-REFERENCE TO RELATED APPLICATION

This application is based upon and claims the benefit of priority from Japanese Patent Application No. 2021-199458, filed Dec. 8, 2021, the entire contents of which are incorporated herein by reference.

### FIELD

Embodiments described herein relate generally to semiconductor devices.

### BACKGROUND

Semiconductor devices may have semiconductor chips mounted on a printed wiring substrate. Electrode terminals for connecting to an external device protrude from a surface on the other side of the printed wiring substrate. Thermal stress or the like may be applied to the electrode terminals, and thus the electrode terminals or the printed wiring substrate may be damaged.

### DESCRIPTION OF THE DRAWINGS

FIG. 1 is a perspective view illustrating an example of a configuration of a semiconductor system according to a first embodiment.

FIGS. 2A and 2B are schematic diagrams illustrating an example of the configuration of a semiconductor device according to the first embodiment.

FIGS. 3A and 3B are diagrams illustrating an example of a detailed configuration of an electrode terminal provided in the semiconductor device according to the first embodiment.

FIGS. 4A to 4G are cross-sectional views illustrating a portion of a procedure of a method for manufacturing a semiconductor device according to the first embodiment in order.

FIGS. 5A and 5B are schematic diagrams illustrating a simulation result of thermal stress applied to an electrode terminal of a semiconductor system according to Comparative Example.

FIG. 6 is a cross-sectional view illustrating an example of a detailed configuration of an electrode terminal provided in a semiconductor device according to Modified Example 1 of the first embodiment.

FIGS. 7A to 7G are cross-sectional views illustrating a portion of a procedure of a method for manufacturing the semiconductor device according to Modified Example 1 of the first embodiment in order.

FIGS. 8A and 8B are diagrams illustrating an example of a detailed configuration of an electrode terminal provided in a semiconductor device according to Modified Example 2 of the first embodiment.

FIGS. 9A to 9C are diagrams illustrating an example of a detailed configuration of an electrode terminal provided in a semiconductor device according to a second embodiment.

FIGS. 10A to 10D are cross-sectional views illustrating a portion of a procedure of a method for manufacturing a semiconductor device according to the second embodiment in order.

FIGS. 11AA to 11BB are diagrams illustrating an example of a detailed configuration of an electrode terminal and a dummy terminal provided in a semiconductor device according to a third embodiment.

FIG. 12 is a schematic diagram illustrating thermal stress applied to a dummy terminal of the semiconductor system according to Comparative Example.

FIGS. 13A and 13B are diagrams illustrating an example of a detailed configuration of a dummy terminal provided in a semiconductor device according to Modified Example 1 of the third embodiment.

FIG. 14 is a cross-sectional view illustrating an example of a detailed configuration of a dummy terminal provided in a semiconductor device according to Modified Example 2 of the third embodiment.

### DETAILED DESCRIPTION

Embodiments provide a semiconductor device capable of reducing influence of stress applied to an electrode terminal.

In general, according to at least one embodiment, a semiconductor device includes: a printed wiring substrate; a semiconductor chip mounted on a first surface of the printed wiring substrate; a sealing resin sealing the semiconductor chip on the first surface of the printed wiring substrate; an electrode pad provided on a second surface on a side opposite to the first surface of the printed wiring substrate; an electrode terminal connected to the electrode pad and protruding from the second surface; and a metal layer provided on a surface of the electrode pad on the electrode terminal side or on the side opposite to the electrode terminal so as to straddle a boundary line of the bonding surface between the electrode terminal and the electrode pad which is at least a boundary line on a side facing an outside of a mounting region of the semiconductor chip.

Hereinafter, the embodiments will be described in detail with reference to the drawings. The present disclosure is not limited to the following embodiments. In addition, components in the following embodiments include those that can be easily assumed by those skilled in the art or those that are substantially the same.

### First Embodiment

Hereinafter, a first embodiment will be described in detail with reference to the drawings.

### Example of Configuration of Semiconductor Device

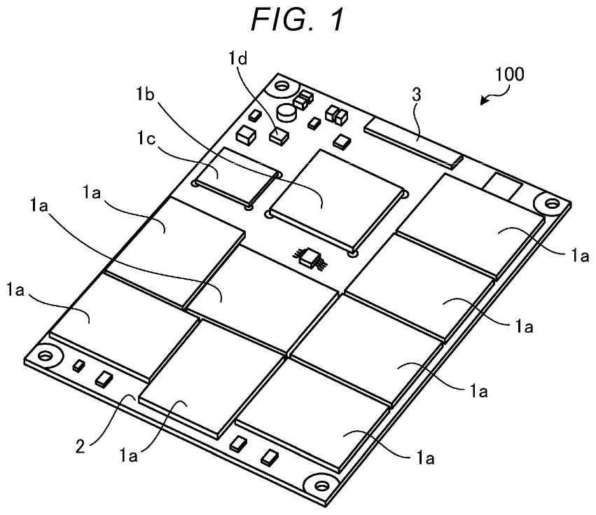

FIG. 1 is a perspective view illustrating an example of a configuration of a semiconductor system 100 according to the first embodiment. As illustrated in FIG. 1, the semiconductor system 100 includes a plurality of semiconductor devices 1 (1a to 1d), a mounting substrate 2, and a connector 3.

Each of the plurality of semiconductor devices 1 is configured as a semiconductor package in which semiconductor chips are sealed. Among these components, the semiconductor device 1a incorporates a non-volatile memory such as a NAND flash memory as a semiconductor chip. The semiconductor device 1b incorporates a drive control circuit such as a memory controller as a semiconductor chip. The drive control circuit controls operations of the non-volatile memory. The semiconductor device 1c incorporates a volatile memory such as a dynamic random access memory (DRAM) as a semiconductor chip. The semiconductor device 1d incorporates a power supply circuit as a semiconductor chip.

The plurality of semiconductor devices 1 are mounted on the mounting substrate 2. The mounting substrate 2 is also called a mother board. In the example of FIG. 1, eight semiconductor devices 1a, one semiconductor device 1b, one semiconductor device 1c, and one semiconductor device 1d are mounted on the mounting substrate 2. However, the number, types, and combinations of the semiconductor devices 1a to 1d mounted on the mounting substrate 2 may be freely selected.

For example, the connector 3 is provided on one side of short sides of the substantially rectangular mounting substrate 2, and is configured to be connectable to a host (not illustrated).

As described above, the semiconductor system 100 includes the semiconductor device 1 as a memory device and, for example, is configured as a memory system such as a solid state drive (SSD).

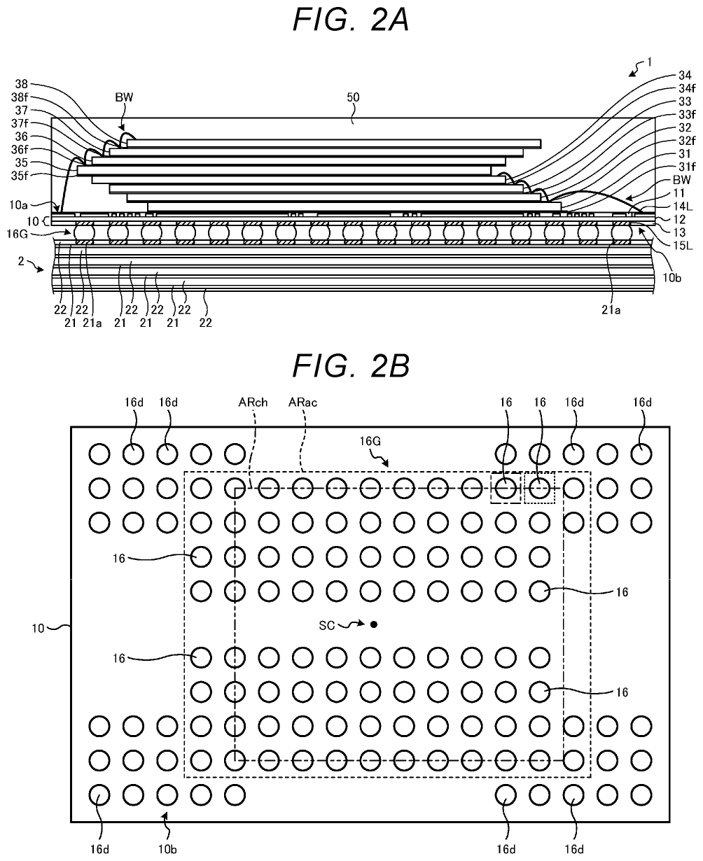

FIGS. 2A and 2B are schematic diagrams illustrating an example of a configuration of the semiconductor device 1 according to the first embodiment. FIG. 2A is a cross-sectional view of the semiconductor device 1 illustrating a state of being mounted on the mounting substrate 2. FIG. 2B is a top view of a surface 10b on one side of a printed wiring substrate 10 of the semiconductor device 1.

The semiconductor device 1 illustrated in FIGS. 2A and 2B may be any of the above-mentioned semiconductor devices 1a to 1d, and any of the above-mentioned semiconductor devices 1a to 1d may have a configuration illustrated in FIGS. 2A and 2B.

As illustrated in FIG. 2A, the semiconductor device 1 includes a plurality of semiconductor chips 31 to 38, the printed wiring substrate 10, and a ball grid array 16G.

The printed wiring substrate (printed circuit board (PCB)) 10 includes solder resist layers 11 and 13, a core layer 12, and conductive layers 14L and 15L.

The core layer 12 is a prepreg or the like which is disposed in the center of the printed wiring substrate 10 and is made of carbon fiber, glass fiber, aramid fiber or the like impregnated with a thermosetting resin such as an epoxy resin before curing. The conductive layer 14L is provided on one surface of the core layer 12, and the conductive layer 14L is covered with the solder resist layer 11. The conductive layer 15L is provided on a surface on the other side of the core layer 12, and the conductive layer 15L is covered with the solder resist layer 13. The solder resist layers 11 and 13 are, for example, insulating resin layers and protect the conductive layers 14L and 15L.

Hereinafter, the surface of the printed wiring substrate 10 on the side where the conductive layer 14L and the solder resist layer 11 are provided is referred to as a surface 10a which is a first surface. The surface of the printed wiring substrate 10 on the side where the conductive layer 15L and the solder resist layer 13 are provided is referred to as a surface 10b which is a second surface.

The plurality of semiconductor chips 31 to 38 are mounted on the surface 10a of the printed wiring substrate 10. However, the number of semiconductor chips 31 to 38 is freely selected, and one or more semiconductor chips are mounted on the printed wiring substrate 10. As mentioned above, these semiconductor chips 31 to 38 incorporate the non-volatile memories, the memory controllers, or other circuits.

The semiconductor chips 31 to 38 are stacked in order by adhesive films 31f to 38f, respectively. These adhesive films 31f to 38f are, for example, a die attach film (DAF), a die bonding film (DBF), or the like.

More specifically, the semiconductor chip 31 is fixed on the surface 10a of the printed wiring substrate 10 by the adhesive film 31f. The semiconductor chip 32 is fixed on the semiconductor chip 31 by the adhesive film 32f, and the semiconductor chip 33 is fixed on the semiconductor chip 32 by the adhesive film 33f. The uppermost semiconductor chip 38 is fixed on the semiconductor chip 37 by the adhesive film 38f.

At this time, the semiconductor chips 31 to 38 are stacked so as to be shifted from each other in a predetermined direction along the surface 10a of the printed wiring substrate 10.

That is, the semiconductor chip 32 is fixed to the semiconductor chip 31 at the position shifted in a predetermined direction along the surface 10a from the mounting position of the semiconductor chip 31. The semiconductor chip 33 is fixed to the semiconductor chip 32 at the position further shifted in a predetermined direction along the surface 10a from the mounting position of the semiconductor chip 32. In this manner, the semiconductor chips are sequentially shifted in a predetermined direction up to the semiconductor chip 35.

Meanwhile, the semiconductor chip 36 and the subsequent chips are stacked so as to be shifted in a reverse direction with respect to, for example, the semiconductor chips 31 to 35. That is, the semiconductor chip 36 is fixed to the semiconductor chip 35 at the position shifted in a reverse direction from the mounting position of the semiconductor chip 35. The semiconductor chip 37 is fixed to the semiconductor chip 36 at the position further shifted in a reverse direction from the mounting position of the semiconductor chip 36. In this manner, the semiconductor chip is sequentially shifted in a reverse direction with respect to the semiconductor chips 31 to 35 up to the semiconductor chip 38.

By shifting the semiconductor chips 31 to 38 in the direction along the surface 10a of the printed wiring substrate 10, the space is generated on the upper surface of each of the semiconductor chips 31 to 38. An electrode (not illustrated) is provided in each of these spaces generated in the semiconductor chips 31 to 38. These electrodes are electrically connected to the conductive layer 14L provided on the surface 10a of the printed wiring substrate 10 by the bonding wire BW.

Accordingly, the semiconductor chips 31 to 38 are wire-bonded to the printed wiring substrate 10 in a face-up state. The sealing resin 50 seals these semiconductor chips 31 to 38 on the surface 10a of the printed wiring substrate 10.

The ball grid array 16G is provided on the surface 10b of the printed wiring substrate 10. The ball grid array 16G includes a plurality of electrode terminals 16. Each of the plurality of electrode terminals 16 is connected to the conductive layer 15L and protrudes from the surface 10b.

That is, in principle, each of the electrode terminals 16 is electrically connected to any one of the semiconductor chips 31 to 38 via the conductive layer 15L, and any signal is assigned to each of the electrode terminals 16. Each of the plurality of electrode terminals 16 is connected to an electrode pad 21a provided on the mounting substrate 2 and is configured as an external connection terminal of the semiconductor device 1.

The mounting substrate 2 is configured as, for example, a multilayer substrate in which an insulating layer 22 and the conductive layer 21 are alternately stacked multiple times. The electrode pad 21a connected to the plurality of electrode terminals 16 is connected to the uppermost layer, that is, the conductive layer 21 closest to the printed wiring substrate 10.

As illustrated in FIG. 2B, the plurality of electrode terminals 16 are located on the surface 10b of the printed wiring substrate 10 in a grid shape to form the ball grid array 16G. A region ARac in which the plurality of electrode terminals 16 are located has a substantially rectangular shape.

In FIG. 2B, a mounting region ARch of the semiconductor chip 31 when viewed from the surface 10b side of the printed wiring substrate 10 is illustrated in the region ARac. Further, a center point SC of the semiconductor chip 31 when viewed from the surface 10b side of the printed wiring substrate 10 is illustrated in the mounting region ARch.

The mounting region ARch overlaps the semiconductor chip 31 when viewed from the surface 10b side of the printed wiring substrate 10.

As described above, the plurality of electrode terminals 16 are located directly under the mounting region ARch of the semiconductor chip 31 and in a peripheral region near the mounting region ARch. Among these terminals, some electrode terminals 16 are provided at positions overlapping the outer edge portion of the mounting region ARch.

A plurality of dummy terminals 16d are provided on the outside of the region ARac. Specifically, the plurality of dummy terminals 16d are located in a grid shape in the vicinity of the four corners of the rectangular region ARac.

In principle, these dummy terminals 16d are not connected to any of the semiconductor chips 31 to 38, are electrically in a floating state and do not contribute to the electrical function of the semiconductor device 1. However, some of the dummy terminals 16d may be used as, for example, test pins in shipping inspection of the semiconductor device 1. Even in this case, the dummy terminals 16d can be identified from the fact that the dummy terminals are provided outside the region ARac.

Further, in some cases, among the plurality of electrode terminals 16, there may be unused electrode terminals 16 that are not electrically connected to any of the semiconductor chips 31 to 38. Therefore, the unused electrode terminal 16 can also be electrically in a floating state, but is distinguished from the dummy terminal 16d provided outside the region ARac. With the standardization of the specifications of the ball grid array 16G, the unused electrode terminals 16 may be provided in the ball grid array 16G as described above.

As described above, the semiconductor device 1 is configured as a ball grid array (BGA) type semiconductor package in which the plurality of electrode terminals 16 are located in a grid shape.

### Example of Configuration of Electrode Terminal

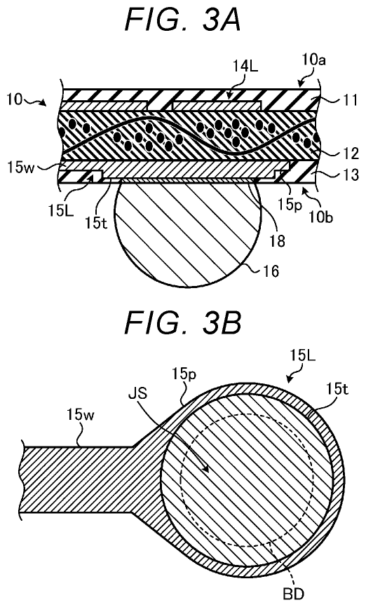

Next, an example of the detailed configuration of the electrode terminal 16 provided on the printed wiring substrate 10 will be described with reference to FIGS. 3A and 3B.

FIGS. 3A and 3B are diagrams illustrating an example of the detailed configuration of the electrode terminal 16 provided in the semiconductor device 1 according to the first embodiment. FIG. 3A is a cross-sectional view of the electrode terminal 16 in the state of being connected to the conductive layer 15L of the printed wiring substrate 10. FIG. 3B is a top view of a connection portion of the conductive layer 15L of the printed wiring substrate 10 with the electrode terminal 16. In FIG. 3B, only the conductive layer 15L is illustrated, and an intervening layer 18 and the electrode terminal 16 are omitted.

As illustrated in FIGS. 3A and 3B, the conductive layer 15L provided on the surface 10b of the printed wiring substrate 10 is, for example, a Cu plating layer or the like and includes a wiring 15w, an electrode pad 15p, and a reinforcing portion 15t.

The wiring 15w extends to the electrode terminal 16 on the core layer 12 on the surface 10b side of the printed wiring substrate 10. The electrode pad 15p is provided integrally with the wiring 15w at a distal end portion of the wiring 15w and has, for example, a circular shape having a diameter larger than the width of the wiring 15w. On the electrode pad 15p, for example, the reinforcing portion 15t having a diameter smaller than that of the electrode pad 15p is provided integrally with the electrode pad 15p.

In other words, the conductive layer 15L is partially thickened in the electrode pad 15p portion, and the reinforcing portion 15t as a metal layer includes a thickened portion of the electrode pad 15p.

The electrode terminal 16 is a solder alloy or the like formed in a substantially hemispherical shape and is also called a solder ball or a solder bump. The base of the hemispherical electrode terminal 16 is bonded to the reinforcing portion 15t as a portion of the electrode pad 15p via the intervening layer 18.

As illustrated in FIG. 3B, a bonding surface JS between the electrode terminal 16 and the reinforcing portion 15t has a diameter smaller than that of the reinforcing portion 15t, and the outer edge portion of the portion where the electrode terminal 16 is bonded to the reinforcing portion 15t, that is, the boundary line BD of the bonding surface JS is located inside the outer edge portion of the reinforcing portion 15t.

The intervening layer 18 is a surface treatment layer such as an Ni plating layer, an Ni/Au plating layer, an Ni/Pd plating layer, or an Ni/Pd/Au plating layer and is located in the region illustrated by the boundary line BD in FIG. 3B, that is, the region substantially matching with the bonding surface JS. By performing an Ni plating process on a surface of the electrode pad 15p which is the Cu plating layer or the like (more specifically, the surface of the reinforcing portion 15t), oxidation of the Cu plating layer or the like is reduced, and the contact resistance with the electrode terminal 16 can be reduced.

Further, by performing an Ni/Au plating process instead of the Ni plating process, the contact resistance with the electrode terminal 16 can be further reduced, and the solder wettability can be improved to increase the bonding strength with the electrode terminal 16. However, after being bonded to the electrode terminal 16, Au may be diffused in the electrode terminal 16 and may not be detected on the bonding surface JS between the electrode terminal 16 and the electrode pad 15p.

### Method for Manufacturing Semiconductor Device

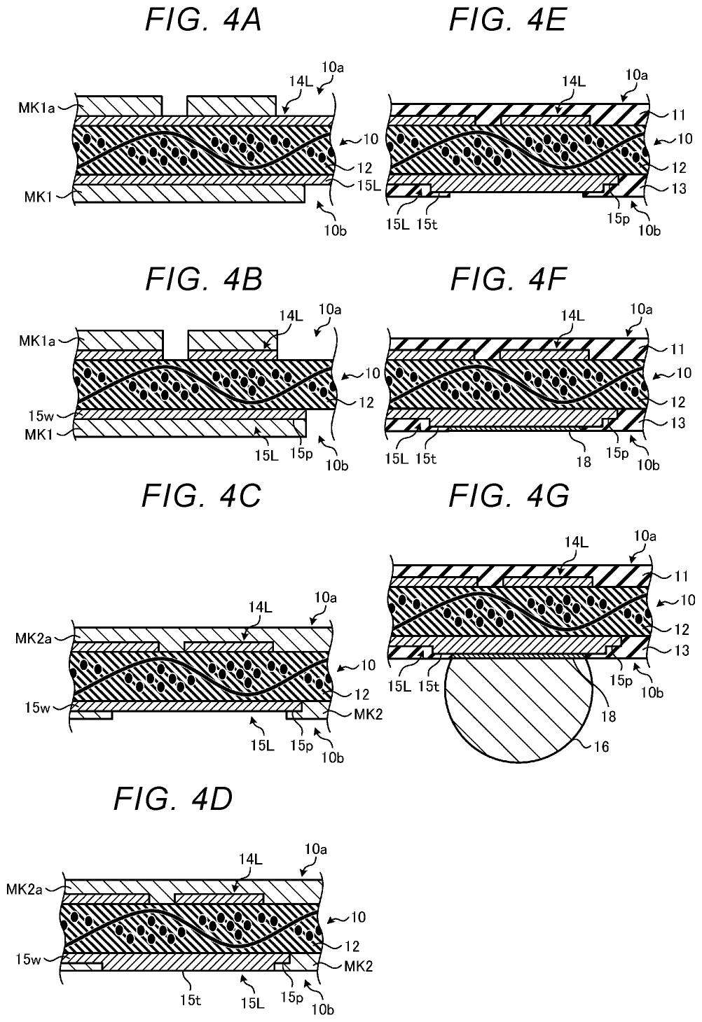

Next, a method for manufacturing the semiconductor device 1 according to the first embodiment will be described with reference to FIGS. 4A to 4G. FIGS. 4A to 4G are cross-sectional views illustrating a portion of a procedure of the method for manufacturing the semiconductor device 1 according to the first embodiment in order. FIGS. 4A to 4G illustrate a process mainly related to formation of the electrode terminal 16 portion among the process of manufacturing the semiconductor device 1.

As illustrated in FIG. 4A, the conductive layer 14L is formed on the entire surface of the core layer 12 on the surface 10a side of the printed wiring substrate 10.

Further, the conductive layer 15L is formed by attaching a metal thin piece such as a copper foil to the entire surface of the core layer 12 on the surface 10b side of the printed wiring substrate 10. At this time, if necessary, the plating process of Cu or the like may be added. It is noted that the materials of the conductive layers 14L and 15L may be the same or may be different.

Further, a mask layer MK1a having a predetermined pattern is formed on the conductive layer 14L. Further, a mask layer MK1 having the pattern of the wiring 15w, the electrode pad 15p, or the like is formed on the conductive layer 15L. The mask layers MK1a and MK1 are photosensitive resin layers of photoresist or the like.

As illustrated in FIG. 4B, the conductive layers 14L and 15L are etched while a portion thereof is protected by the mask layers MK1a and MK1. Accordingly, the conductive layer 14L is molded into a predetermined pattern. Further, the conductive layer 15L is molded into the pattern of the wiring 15w, the electrode pad 15p, or the like. After that, the mask layers MK1a and MK1 are removed.

As illustrated in FIG. 4C, a mask layer MK2 having a pattern opening of the reinforcing portion 15t is formed on the electrode pad 15p formed on the conductive layer 15L. Meanwhile, a mask layer MK2a is formed on the entire surface on the surface 10a side including the conductive layer 14L molded into a predetermined pattern.

As illustrated in FIG. 4D, the reinforcing portion 15t is formed integrally with the electrode pad 15p by plating the opening of the mask layer MK2 with Cu or the like. At this time, since the surface 10a side is protected by the mask layer MK1a, the formed pattern of the conductive layer 14L is maintained. After that, the mask layers MK2a and MK2 are removed.

As illustrated in FIG. 4E, the solder resist layer 13 having the opening is formed on the reinforcing portion 15t. In parallel with this, the solder resist layer 11 covering the conductive layer 14L on the surface 10a side is formed. At this time, the solder resist layer 11 may be provided with the opening (not illustrated) to partially expose the conductive layer 14L.

As illustrated in FIG. 4F, the intervening layer 18 is formed on the reinforcing portion 15t by performing an electrolytic Ni plating process, an electrolytic Ni/Au plating process, an electrolytic Ni/Pd/Au plating process, or the like on the opening of the solder resist layer 13.

Further, although not illustrated, the plurality of semiconductor chips 31 to 38 are sequentially stacked on the surface 10a of the printed wiring substrate 10 via the adhesive films 31f to 38f, and after the electrodes on the upper surfaces of the semiconductor chips 31 to 38 are connected to the exposed portion of the conductive layer 14L of the printed wiring substrate 10 by the bonding wire BW, the semiconductor chips 31 to 38 are sealed on the printed wiring substrate 10.

As illustrated in FIG. 4G, by performing soldering on the reinforcing portion 15t via the intervening layer 18, for example, the substantially hemispherical electrode terminal 16 is bonded to the reinforcing portion 15t.

As described above, the semiconductor device 1 of the first embodiment is manufactured.

### Comparative Example

Stress may occur in the electrode terminals of the semiconductor device due to expansion/contraction of each member of the semiconductor device. Specifically, in the semiconductor system, in some cases, in a state where the semiconductor device is mounted on the mounting substrate, the stress may be applied to the electrode terminal connecting the semiconductor device and the mounting substrate due to a difference in a linear expansion coefficient between the semiconductor chip and the mounting substrate in the semiconductor device.

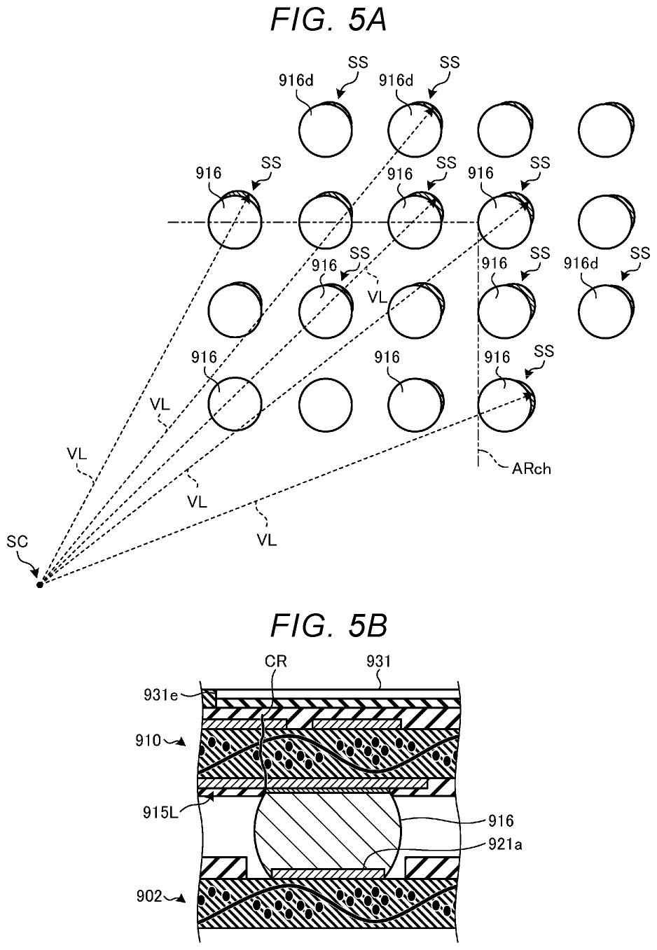

The present inventors perform a mounting temperature cycling test (TCT) as one of design validation tests (DVTs) on a semiconductor system of Comparative Example. In the mounting TCT, the semiconductor system is repeatedly exposed to low temperature/high temperature to check resistance thereof. Accordingly, the influence of the thermal stress applied to the electrode terminals of the semiconductor device becomes more significant. FIGS. 5A and 5B illustrate a structure of an electrode terminal 916 provided in the semiconductor system of Comparative Example and a simulation result of the thermal stress applied to the electrode terminal 916.

FIGS. 5A and 5B are schematic diagrams illustrating the thermal stress applied to the electrode terminal 916 of the semiconductor system according to Comparative Example. FIG. 5A is a plan view illustrating the simulation result of the thermal stress applied to the electrode terminal 916. FIG. 5B is a cross-sectional view of the electrode terminal 916 in the semiconductor system of Comparative Example.

As illustrated in FIGS. 5A and 5B, the electrode terminal 916 of Comparative Example is bonded to a conductive layer 915L having a substantially uniform thickness via the intervening layer. That is, the electrode pad is not thickened in the conductive layer 915L provided in a printed wiring substrate 910 of Comparative Example. Further, the lower end portion of the electrode terminal 916 is bonded to an electrode pad 921a provided in a mounting substrate 902.

Further, similarly to the electrode terminal 16 of the first embodiment described above, the electrode terminals 916 of Comparative Example are located in the rectangular region in a grid shape, and dummy terminals 916d are located in the vicinity of the corners having a rectangular shape.

As illustrated in FIG. 5A, according to the thermal stress simulation, it can be seen that thermal stress SS acts on the electrode terminal 916 in the state of being mounted on the mounting substrate 902. Further, it can be seen that the thermal stress SS applied to the electrode terminal 916 has a bias in one electrode terminal 916 and among the plurality of electrode terminals 916.

That is, among the plurality of electrode terminals 916, the thermal stress SS is significant at the electrode terminals 916 located at the position overlapping the outer edge portion of the mounting region ARch of a semiconductor chip 931 and on the outer-edge-portion peripheral edge inside and outside the outer edge portion.

Further, in one electrode terminal 916, the thermal stress SS is significant on the boundary line of the bonding surface with the conductive layer 915L on a side facing the outside of the mounting region ARch, that is, the side farthest from the center point SC of the semiconductor chip 931.

More specifically, when a virtual line VL is drawn from the center point SC of the semiconductor chip 931 toward the center point of each electrode terminal 916, thermal stress is concentrated on the boundary line of a predetermined range centered on the intersection between the virtual line VL and the boundary line on the side facing the outside of the mounting region ARch out of the boundary line of the bonding surface between an electrode terminal 916 and the conductive layer 915L.

As illustrated in FIG. 5B, in some cases, it is found that cracks CR may occur on the printed wiring substrate 910 after the mounting TCT at the electrode terminal 916 located in the vicinity of an end portion position 931e of the semiconductor chip 931 in the mounting region ARch of the semiconductor chip 931 mounted on the printed wiring substrate 910. The cracks CR of the printed wiring substrate 910 are generated starting from a side facing an outside of the mounting region ARch of the semiconductor chip 931 where the thermal stress is significant out of the outer edge portion of the electrode terminal 916 bonded to the conductive layer 915L.

It is noted that, according to the thermal stress simulation illustrated in FIG. 5A described above, the electrode terminals 916 located adjacent to the outer edge portion of the mounting region ARch can also receive significant thermal stress in the outside of the mounting region ARch. However, the effect of thermal stress on these electrode terminals 916 is extremely local. That is, it is observed that, the cracks CR starting from the electrode terminals 916 hardly occur or even though the cracks CR occur, the cracks CR do not proceed to the inside of the printed wiring substrate 910.

In the semiconductor device 1 according to the first embodiment, the reinforcing portion 15t which is a thickened portion of the electrode pad 15p is provided in the boundary line BD while straddling the boundary line BD of the bonding surface JS between the electrode terminal 16 and the electrode pad 15p and covers the entire surface overlapping the bonding surface JS.

With the above-described configuration, the conductive layer 15L portion in contact with the outer edge portion of the electrode terminal 16 where the influence of thermal stress is significant is strengthened, and the influence of stress applied to the electrode terminal 16 can be reduced. Therefore, the generation of cracks CR starting from the outer edge portion of the electrode terminal 16 on the printed wiring substrate 10 can be reduced.

Further, for example, when the conductive layer 15L is thickened as a whole, the fine processability of the conductive layer 15L may be impaired. Further, in order to reduce the increase in the thickness of the printed wiring substrate 10, for example, when only the conductive layer 15L on one side is thickened, the stress balance between the conductive layer 14L maintained at the original thickness and the thickened conductive layer 15L collapses, and thus, the warpage of the printed wiring substrate 10 may occur.

With the above-described configuration, since the conductive layer 15L is only locally thickened, the fine processability of the conductive layer 15L can be maintained, and the warpage of the printed wiring substrate 10 can be reduced.

### Modified Example 1

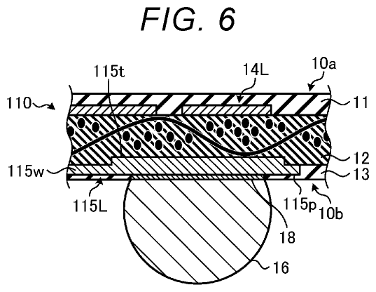

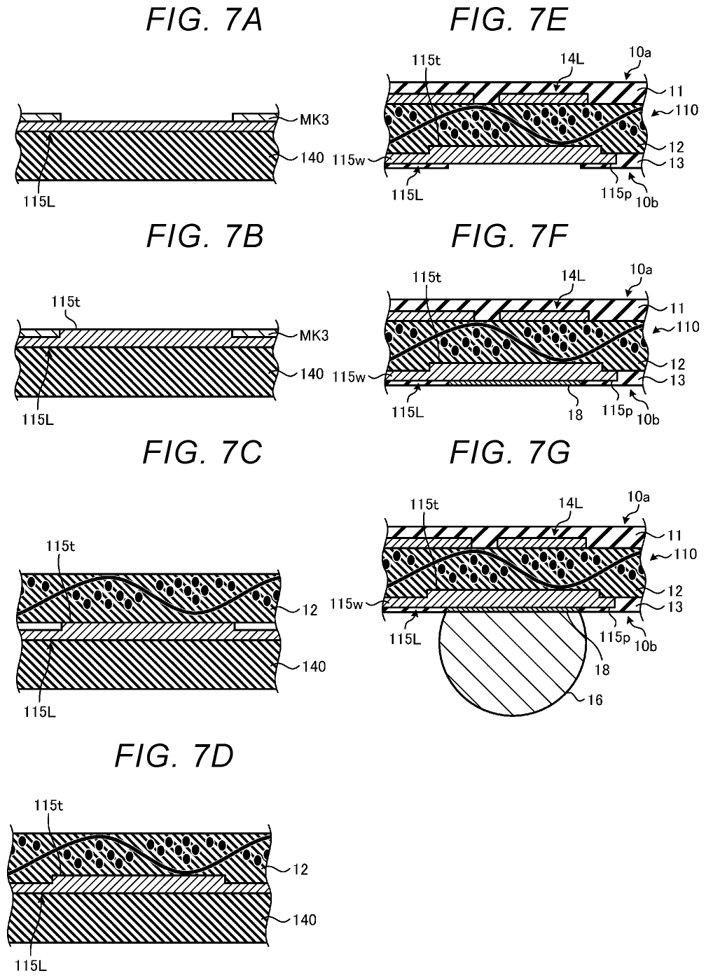

Next, a semiconductor device of Modified Example 1 of the first embodiment will be described with reference to FIGS. 6 and 7. The semiconductor device of Modified Example 1 is different from that of the above-described first embodiment in the arrangement position of a reinforcing portion 115t. In the following, in some cases, the same components as those in the first embodiment may be denoted by the same reference numerals, and the description thereof may be omitted.

FIG. 6 is a cross-sectional view illustrating an example of the detailed configuration of the electrode terminal 16 provided in the semiconductor device according to Modified Example 1 of the first embodiment.

As illustrated in FIG. 6, a printed wiring substrate 110 of Modified Example 1 is provided with a conductive layer 115L on the surface 10b side. The conductive layer 115L is, for example, the Cu plating layer or the like and includes a wiring 115w, an electrode pad 115p, and a reinforcing portion 115t.

The wiring 115w extends to the electrode terminal 16 on the core layer 12 on the surface 10b side of the printed wiring substrate 110. The electrode pad 115p is provided integrally with the wiring 115w at the distal end portion of the wiring 115w and has, for example, a circular shape having a diameter larger than the width of the wiring 115w. The intervening layer 18 is provided on the electrode pad 115p.

For example, the reinforcing portion 115t having a diameter smaller than that of the electrode pad 115p is provided integrally with the electrode pad 115p on a surface of the electrode pad 115p on a side of the core layer 12. For example, the reinforcing portion 115t as a metal layer protrudes into the inside of the core layer 12.

As described above, in the semiconductor device of Modified Example 1, with respect to the configuration of the first embodiment, the reinforcing portion 115t is provided on a surface of the electrode pad 115p on the side opposite thereof.

FIGS. 7A to 7G are cross-sectional views illustrating a portion of a procedure of a method for manufacturing a semiconductor device according to Modified Example 1 of the first embodiment in order. FIGS. 7A to 7G illustrate a process mainly related to formation of a portion of the electrode terminal 16 among the processes of manufacturing the semiconductor device of Modified Example 1.

As illustrated in FIG. 7A, the conductive layer 115L is formed by attaching the metal thin piece of the copper foil or the like to the entire surface of a supporting substrate 140. At this time, if necessary, the plating process of Cu or the like may be added. As the supporting substrate 140, for example, a semiconductor substrate such as a silicon substrate, an insulating substrate such as a ceramics substrate or a glass substrate, a resin substrate, or the like may be used. A mask layer MK3 having a pattern opening of the reinforcing portion 115t is formed on the conductive layer 115L.

As illustrated in FIG. 7B, the reinforcing portion 115t is formed integrally with the conductive layer 115L portion as the lower layer by plating the opening of the mask layer MK3 with Cu or the like. After that, the mask layer MK3 is removed.

As illustrated in FIG. 7C, the pre-cured core layer 12 in which the thermosetting resin is impregnated into carbon fiber or the like is located on the supporting substrate 140.

As illustrated in FIG. 7D, the pre-cured core layer 12 is pressed against the supporting substrate 140. Accordingly, by allowing the conductive layer 115L to be in a close contact with the surface of the core layer 12, the reinforcing portion 115t protruding from the conductive layer 115L enters the core layer 12. After that, by removing the supporting substrate 140, the conductive layer 115L including the reinforcing portion 115t is transferred to the core layer 12 side.

As illustrated in FIG. 7E, the conductive layer 14L is formed on the upper surface of the core layer 12 on the side opposite to the conductive layer 115L. Also in this case, the materials of the conductive layers 14L and 115L may be the same or may be different.

Further, the wiring 115w and the electrode pad 115p are formed on the conductive layer 115L. Similarly to the first embodiment, the wiring 115w and the electrode pad 115p are formed by etching the conductive layer 115L while partially protecting the conductive layer 115L with the mask layer having a pattern of the wiring 115w and the electrode pad 115p. In parallel with this, the conductive layer 14L is also molded into a predetermined pattern.

Further, the solder resist layer 13 having the opening is formed on the electrode pad 115p. The solder resist layer 11 covering the conductive layer 14L is formed on the surface 10a side.

As illustrated in FIG. 7F, the intervening layer 18 is formed on the electrode pad 115p by performing the electrolytic Ni plating process, the electrolytic Ni/Au plating process, the electrolytic Ni/Pd/Au plating process, or the like on the opening of the solder resist layer 13.

Further, the semiconductor chip (not illustrated) is mounted and sealed on the surface 10a of the printed wiring substrate 110.

As illustrated in FIG. 7G, soldering is performed on the electrode pad 115p via the intervening layer 18, for example, the electrode terminal 16 having a substantially hemispherical shape is bonded to the electrode pad 115p.

As described above, the semiconductor device of Modified Example 1 is manufactured.

In the semiconductor device of Modified Example 1, the reinforcing portion 115t which is a thickened portion of the electrode pad 115p is provided on a surface of the electrode pad 115p on the side opposite to the electrode terminal 16. Accordingly, the thickened reinforcing portion 115t can be buried in the core layer 12 of the printed wiring substrate 110, and the thickness of the semiconductor device can be prevented from increasing. Further, the warpage of the printed wiring substrate 110 can be further reduced.

With the semiconductor device of Modified Example 1, the same effects as those of the semiconductor device 1 of the above-described first embodiment are obtained.

### Modified Example 2

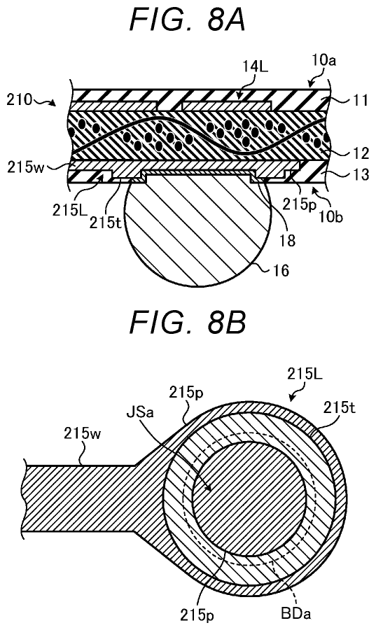

Next, the semiconductor device of Modified Example 2 of the first embodiment will be described with reference to FIGS. 8A and 8B. The shape of a reinforcing portion 215t of the semiconductor device of Modified Example 2 is different from that of the above-described first embodiment. In the following, in some cases, the same components as those in the first embodiment may be denoted by the same reference numerals, and the description thereof may be omitted.

FIGS. 8A and 8B are diagrams illustrating an example of the detailed configuration of the electrode terminal 16 provided in the semiconductor device according to Modified Example 2 of the first embodiment. FIG. 8A is a cross-sectional view of the electrode terminal 16 in the state of being connected to a conductive layer 215L of a printed wiring substrate 210. FIG. 8B is a top view of a connection portion of the conductive layer 215L of the printed wiring substrate 210 with the electrode terminal 16. In FIG. 8B, only the conductive layer 215L is illustrated, and the intervening layer 18 and the electrode terminal 16 are omitted.

As illustrated in FIGS. 8A and 8B, the conductive layer 215L provided on the surface 10b of the printed wiring substrate 210 is, for example, the Cu plating layer or the like and includes a wiring 215w, an electrode pad 215p, and a reinforcing portion 215t. The material of the conductive layer 215L is the same as or different from that of the conductive layer 14L.

The wiring 215w extends to the electrode terminal 16 on the core layer 12 on the surface 10b side of the printed wiring substrate 210. The electrode pad 215p is provided integrally with the wiring 215w at the distal end portion of the wiring 215w and has, for example, a circular shape having a diameter larger than the width of the wiring 215w. On the electrode pad 215p, the reinforcing portion 215t is provided integrally with the electrode pad 215p, for example, in an annular shape having a diameter smaller than that of the electrode pad 215p.

More specifically, the reinforcing portion 215t as a metal layer is provided on the electrode pad 215p in an annular shape along a boundary line BDa of a bonding surface JSa between the electrode terminal 16 and the conductive layer 215L so as to straddle the boundary line BDa. In other words, the reinforcing portion 215t is provided on the electrode pad 215p in an annular shape having a predetermined width, and the boundary line BDa of the bonding surface JSa is located between the outer edge portion and the inner edge portion of the reinforcing portion 215t.

Herein, the bonding surface JSa is a region including a surface of the electrode pad 215p located in the inner region of the annular reinforcing portion 215t and a surface of the reinforcing portion 215t inside the boundary line BDa. Further, the intervening layer 18 is provided in a region substantially matching with the bonding surface JSa in a shape in which a central portion is recessed from the surface of the reinforcing portion 215t to the surface side of the electrode pad 215p inside the reinforcing portion 215t.

The electrode terminal 16 portion as described above in the semiconductor device of Modified Example 2 can be formed by the same method as that of the first embodiment. That is, in the processes of FIGS. 4C and 4D, the above-described shape can be obtained by forming the reinforcing portion 215t in an annular shape.

In the semiconductor device of Modified Example 2, the reinforcing portion 215t which is a thickened portion of the electrode pad 215p is provided to boundary line BDa over the entire boundary line BDa of the bonding surface JS between the electrode terminal 16 and the electrode pad 215p. Accordingly, the thickened portion of the electrode pad 215p becomes more localized, and the warpage of the printed wiring substrate 110 can be further reduced.

With the semiconductor device of Modified Example 2, in addition to this, the same effects as those of the semiconductor device 1 of the above-described first embodiment are obtained.

It is noted that, in the above-mentioned Modified Example 2, the reinforcing portion 215t protrudes toward the electrode terminal 16 side of the electrode pad 215p. However, similarly to the above-mentioned Modified Example 1, the reinforcing portion 215t may be provided on a surface of the electrode pad 215p on the core layer 12 side. Such the electrode terminal 16 portion can be formed by the same method as that of Modified Example 1. That is, in the processes of FIGS. 7A and 7B, the above-described shape can be obtained by forming the reinforcing portion 215t in the annular shape.

Further, in the first embodiment and Modified Examples 1 and 2 described above, the reinforcing portions 15t, 115t, and 215t are provided at the bonding portions of the plurality of electrode terminals 16. However, the reinforcing portion may be provided only in a portion of the bonding portions where the influence of the thermal stress is significant among the plurality of electrode terminals 16 based on the result of the thermal stress simulation illustrated in FIG. 5A described above.

That is, a reinforcing portion can be provided in at least one of the bonding portions of the electrode terminals 16 located at the position overlapping the outer edge portion of the mounting region ARch of the semiconductor chip 31 and the electrode terminal 16 located in the outermost peripheral portion in the mounting region ARch to be adjacent to the outer edge portion of the mounting region ARch among the plurality of electrode terminals 16.

Since the thermal stress acting on the electrode terminals 16 located at the above-described positions is significant, the influence of the stress can be reduced even if the reinforcing portion is provided only for these electrode terminals 16.

It is noted that, since the Cu plating layer and the like used for the conductive layers 15L, 115L, and 215L are relatively inexpensive, as compared with generating individual bonding portions of the electrode terminals 16 by locating the electrode terminals 16, application of the reinforcing portions 15t, 115t, and 215t to the respective ones of the plurality of electrode terminals 16 can be simplified because complicated manufacturing processes can be avoided.

In this case, by applying the reinforcing portions 15t, 115t, and 215t in the above-described first embodiment and Modified Examples 1 and 2 to the dummy terminal 16d as well as the electrode terminal 16, the semiconductor device can be more easily manufactured.

Further, in the first embodiment and Modified Examples 1 and 2 described above, the intervening layer 18 such as the Ni plating layer is provided at the bonding portions of the conductive layers 15L, 115L, and 215L with the electrode terminals 16. However, the electrode terminal 16 may be directly bonded to the conductive layers 15L, 115L, and 215L via no intervening layer 18.

Further, when the intervening layer 18 is not provided in the conductive layers 15L, 115L, and 215L, surface treatment may be performed by applying an organic solderability preservative (OSP) to the bonding portion with the electrode terminal 16. The OSP is a coating agent that selectively binds to Cu and protects conductive layers 15L, 115L, and 215L of the Cu plating layer and the like until the electrode terminal 16 is formed. As examples of the OSP, there are exemplified benzotriazole, imidazole, benzimidazole, and the like.

### Second Embodiment

Hereinafter, a second embodiment will be described in detail with reference to the drawings. The semiconductor device of the second embodiment is different from that of the above-described first embodiment in that the bonding portion of the electrode terminals is strengthened by the intervening layer. In the following, in some cases, the same components as those in the first embodiment may be denoted by the same reference numerals, and the description thereof may be omitted.

### Example of Configuration of Electrode Terminal

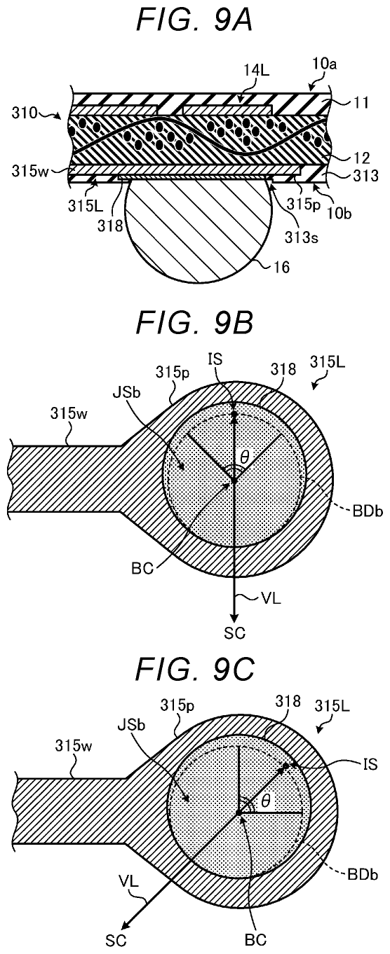

FIGS. 9A to 9C are diagrams illustrating an example of the detailed configuration of the electrode terminal 16 provided in the semiconductor device according to the second embodiment. FIG. 9A is a cross-sectional view of the electrode terminal 16 in the state of being connected to a conductive layer 315L of a printed wiring substrate 310. FIGS. 9B and 9C are top views of a connection portion of the conductive layer 315L of the printed wiring substrate 310 with the electrode terminal 16. In FIGS. 9B and 9C, the conductive layer 315L and an intervening layer 318 are illustrated, and the electrode terminal 16 is omitted.

It is noted that the electrode terminal 16 illustrated in FIGS. 9A to 9C is located at the position overlapping the outer edge portion of the mounting region of the semiconductor chip mounted on the printed wiring substrate 310 or at the outermost peripheral portion in the mounting region of the semiconductor chip.

As illustrated in FIGS. 9A to 9C, the conductive layer 315L provided on the surface 10b of the printed wiring substrate 310 is, for example, the Cu plating layer or the like and includes a wiring 315w and an electrode pad 315p. The wiring 315w extends to the electrode terminal 16 on the core layer 12 on the surface 10b side of the printed wiring substrate 310. The electrode pad 315p is provided integrally with the wiring 315w at the distal end portion of the wiring 315w and has, for example, a circular shape having a diameter larger than the width of the wiring 315w.

The electrode terminal 16 is bonded to the electrode pad 315p via the intervening layer 318 as a metal layer. The intervening layer 318 is a surface treatment layer such as an Ni plating layer, an Ni/Au plating layer, an Ni/Pd plating layer, or an Ni/Pd/Au plating layer and reduces oxidation of a surface of the electrode pad 315p and increases the bonding strength between the electrode terminal 16 and the electrode pad 315p.

As illustrated in FIGS. 9B and 9C, a bonding surface JSb between the electrode terminal 16 and the electrode pad 315p has a diameter smaller than the diameter of the intervening layer 318 having a substantially circular shape, and a boundary line BDb of the bonding surface JSb is located inside the outer edge portion of the intervening layer 318.

A center point BC of the electrode terminal 16 viewed from the surface 10b side of the printed wiring substrate 310 does not match with the center point of the intervening layer 318, and the arrangement position of the intervening layer 318 is eccentric toward the outside of the mounting region of the semiconductor chip with respect to the electrode terminal 16 having a substantially hemispherical shape.

It is noted that the center point BC of the electrode terminal 16 substantially matches with the center point of the bonding surface JSb. For this reason, the intervening layer 318 extends in the above-mentioned eccentric direction, that is, toward the outside of the mounting region of the semiconductor chip, beyond the boundary line BDb of the bonding surface JSb. This point will be described in more detail below.

FIGS. 9B and 9C illustrate the center point SC of the semiconductor chip mounted on the printed wiring substrate 310 when viewed from the surface 10b side of the printed wiring substrate 310 and the virtual line VL connecting the center point SC of the semiconductor chip and the center points BC of the electrode terminal 16 illustrated in FIGS. 9B and 9C.

As illustrated in FIGS. 9B and 9C, the intervening layer 318 extends beyond the boundary line BDb of the bonding surface JSb between the electrode terminal 16 and the electrode pad 315p over a predetermined range of the boundary line BDb including an intersection IS between the boundary line BDb on the side facing the outside of the mounting region of the semiconductor chip and the virtual line VL extending toward the outside of the mounting region of the semiconductor chip.

In FIG. 9B, the center point SC of the semiconductor chip is located below the paper surface with respect to the electrode terminal 16, and the upper side of the electrode terminal 16 is the side facing the outside of the mounting region of the semiconductor chip. Therefore, the intervening layer 318 extends beyond the boundary line BDb over a predetermined range of the boundary line BDb on the upper side of the paper surface.

In FIG. 9C, the center point SC of the semiconductor chip is located obliquely downward to the left of the paper surface with respect to the electrode terminal 16, and an oblique upper right side of the electrode terminal 16 is the side facing the outside of the mounting region of the semiconductor chip. Therefore, the intervening layer 318 extends beyond the boundary line BDb over a predetermined range of the boundary line BDb on the oblique upper right side of the paper surface.

More specifically, the intervening layer 318 extends beyond the boundary line BDb included in a predetermined angle θ from the center point BC of the electrode terminal 16 toward the outside of the mounting region. The range in which the intervening layer 318 extends beyond the boundary line BDb is a range in which significant stress concentration is observed in the electrode terminal 16, for example, a range in which the angle θ is 90° or more and less than 180°.

Further, on the surface 10b side of the printed wiring substrate 310, the solder resist layer 313 having the opening on the electrode pad 315p provided with the intervening layer 318 covers the conductive layer 315L.

In FIG. 9A, the left side of the paper surface is the side facing the outside of the mounting region of the semiconductor chip, and the intervening layer 318 is eccentric toward the left side of the paper surface with respect to the electrode terminal 16. The solder resist layer 313 covers the intervening layer 318 on the side eccentric with respect to the electrode terminal 16, that is, of the portion extending beyond the boundary line BDb of the bonding surface JSb with the electrode terminal 16.

Further, in some cases, the solder resist layer 313 may have a step difference 313s in the vicinity of the intervening layer 318 on a reverse side with respect to the direction in which the intervening layer 318 extends beyond the boundary line BDb.

It is noted that, in the semiconductor device of the second embodiment, for the electrode terminal 16 other than the electrode terminal 16 illustrated in FIGS. 9A to 9C, that is, the electrode terminal 16 located inside the outermost peripheral portion in the mounting region of the semiconductor chip and the electrode terminal 16 located outside the mounting region of the semiconductor chip that do not overlap the outer peripheral portion of the mounting region of the semiconductor chip, similarly to the intervening layer 18 of the first embodiment described above, the intervening layer has a diameter substantially equal to that of the bonding surface JSb between the electrode terminal 16 and the electrode pad 315p and is provided at the position substantially overlapping the bonding surface JSb.

### Method for Manufacturing Semiconductor Device

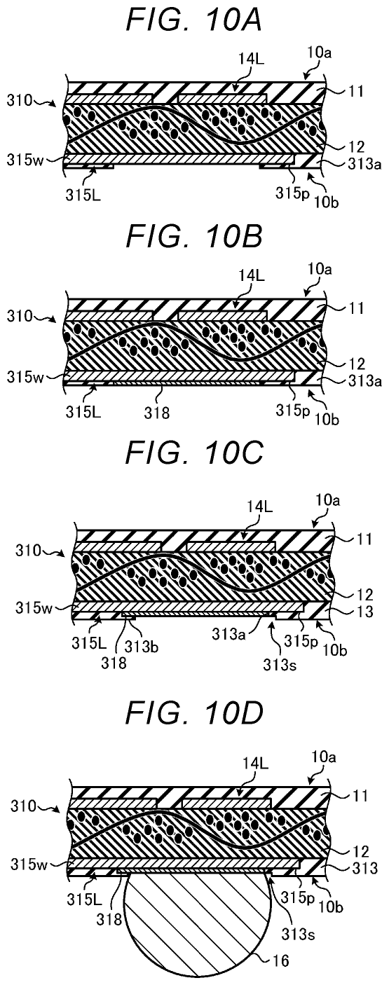

Next, a method for manufacturing the semiconductor device according to the second embodiment will be described with reference to FIGS. 10A to 10D. FIGS. 10A to 10D are a cross-sectional views illustrating a portion of a procedure of the method for manufacturing the semiconductor device according to the second embodiment in order. FIGS. 10A to 10D illustrate a process mainly related to the formation of the electrode terminal 16 portion among the processes of manufacturing the semiconductor device of the second embodiment.

As illustrated in FIG. 10A, the conductive layer 14L is formed on the upper surface of the core layer 12 on the surface 10a side of the printed wiring substrate 10.

Further, in parallel with this, for example, similarly to the above-described first embodiment, the conductive layer 315L including the wiring 315w and the electrode pad 315p is formed on the upper surface of the core layer 12 on the surface 10b side of the printed wiring substrate 10. Also in this case, the materials of the conductive layers 14L and 315L may be the same or may be different.

Further, a solder resist layer 313a having the opening is formed on the electrode pad 315p. The opening of the solder resist layer 313a has a size substantially equal to that of the intervening layer 318 formed later and to be eccentric to the outside of the mounting region of the semiconductor chip with respect to the electrode pad 315p. The solder resist layer 11 that covers the conductive layer 14L is formed on the surface 10a side.

As illustrated in FIG. 10B, the intervening layer 318 is formed on the electrode pad 315p by performing the electrolytic Ni plating process, the electrolytic Ni/Au plating process, the electrolytic Ni/Pd/Au plating process, or the like on the opening of the solder resist layer 313a.

As illustrated in FIG. 10C, a solder resist layer 313b having the opening on the intervening layer 318 is formed on the solder resist layer 313a. The opening of the solder resist layer 313b is formed in a size substantially equal to the bonding surface JSb at the position substantially matching with the bonding surface JSb (refer to FIGS. 9A to 9C) with the electrode terminal 16 which is to be later bonded to the electrode pad 315p.

By locating the opening of the solder resist layer 313b as described above, the surface of the intervening layer 318 in the portion which is eccentric with respect to the electrode pad 315p is covered with the solder resist layer 313b. Accordingly, the electrode terminal 16 can be formed in a substantially central portion of the electrode pad 315p even when the intervening layer 318 is eccentric with respect to the electrode pad 315p.

In other words, the bonding position of the electrode terminal 16 which is to be formed later and the size of the bonding surface JSb are defined by the opening of the solder resist layer 313b.

However, according to the alignment accuracy with respect to the intervening layer 318, the opening of the solder resist layer 313b may have a size slightly larger than the size of the planned bonding surface JSb. Accordingly, the end portion of the intervening layer 318 on a reverse side with respect to the eccentric direction can be prevented from being covered with the solder resist layer 313b, and the bonding surface JSb can be prevented from being smaller than a specified value. At this time, the step difference 313s due to the solder resist layer 313b is formed in the vicinity of the end portion of the intervening layer 318 on the reverse side with respect to the eccentric direction.

After that, the semiconductor chip (not illustrated) is mounted and sealed on the surface 10a of the printed wiring substrate 310.

Accordingly, the solder resist layer 313 including the solder resist layers 313a and 313b is formed.

As illustrated in FIG. 10D, soldering is performed on the electrode pad 315p via the intervening layer 318, and for example, the substantially hemispherical electrode terminal 16 is bonded to the electrode pad 315p.

As described above, the semiconductor device of the second embodiment is manufactured.

### SUMMARY

In the semiconductor device of the second embodiment, the intervening layer 318 straddling the boundary line BDb of the bonding surface JSb between the electrode terminal 16 and the electrode pad 315p is provided at the position overlapping the outer edge portion of the mounting region of the semiconductor chip in the printed wiring substrate 310 or in the electrode terminal 16 located at the outermost peripheral portion in the mounting region in the ball grid array.

Accordingly, the conductive layer 315L portion bonded to the electrode terminal 16 to which the influence of thermal stress is significant among the plurality of electrode terminals 16 provided in the ball grid array is strengthened, and the influence of the stress applied to the electrode terminal 16 can be reduced. Therefore, the occurrence of cracks starting from the outer edge portion of the electrode terminal 16 on the printed wiring substrate 310 can be reduced.

Further, the cost of the material of the intervening layer 318 which is the Ni plating layer or the like is higher than that of the conductive layer 315L which is the Cu plating layer or the like. As described above, for example, only in the electrode terminal 16 where the influence of thermal stress is significant, by providing the intervening layer 318 having a large area with respect to the bonding surface JSb, the amount of use of the plating material such as Ni of the intervening layer 318 can be reduced, and the manufacturing cost of the semiconductor device of the second embodiment can be reduced.

In the semiconductor device of the second embodiment, the intervening layer 318 covers the entire bonding surface JSb between the electrode terminal 16 and the electrode pad 315p and extends beyond the boundary line BDb of the bonding surface JSb toward the outside of the mounting region of the semiconductor chip.

In this manner, for example, in the electrode terminal 16 where the influence of thermal stress is significant, only the portion facing the outside of the mounting region of the semiconductor chip on which the thermal stress is more likely to be concentrated is strengthened by the intervening layer 318, and thus, the amount of usage of the plating material such as Ni can be further reduced.

Further, by reducing the area of the intervening layer 318, the area of the bonding surface JSb can be prevented from increasing, and the wiring capacitance can be reduced. Further, since the electrode pad 315p can be formed compactly, the density and the degree of freedom of arrangement of the electrode pad 315p and the wiring 315w associated therewith are improved.

In the semiconductor device of the second embodiment, the range in which the intervening layer 318 extends beyond the boundary line BDb of the bonding surface JSb of the electrode terminal 16 is a range of 90° or more and less than 180°, which extends from the center point BC of the electrode terminal 16 toward the outside of the mounting region of the semiconductor chip.

According to the result of the thermal stress simulation illustrated in FIG. 5A described above, it is known that the stress concentration is significant in the boundary line BDb portion located in the range where the angle θ (refer to FIGS. 9A to 9C) defined as described above is 90° or more and less than 180°. By extending the intervening layer 318 beyond the boundary line BDb in the above-described range, the influence of the stress applied to the electrode terminal 16 can be reduced while reducing the cost of the material of the intervening layer 318.

It is noted that, in the above-mentioned second embodiment, the intervening layer 318 is formed in a substantially circular shape. However, as long as the boundary line BDb portion located in the range where the angle θ is 90° or more and less than 180° can be reinforced, the shape of the intervening layer 318 is not limited thereto. As an example, the shape of the intervening layer 318 may be an oval shape protruding toward the outside of the mounting region of the semiconductor chip.

### Third Embodiment

Hereinafter, a third embodiment will be described in detail with reference to the drawings. The semiconductor device of the third embodiment is different from that of the above-described first and second embodiments in that the bonding portion is strengthened with respect to the dummy terminal. In the following, in some cases, the same configurations as those of the above-described first and second embodiments may be designated by the same reference numerals, and the description thereof may be omitted.

### Example of Configuration of Electrode Terminal

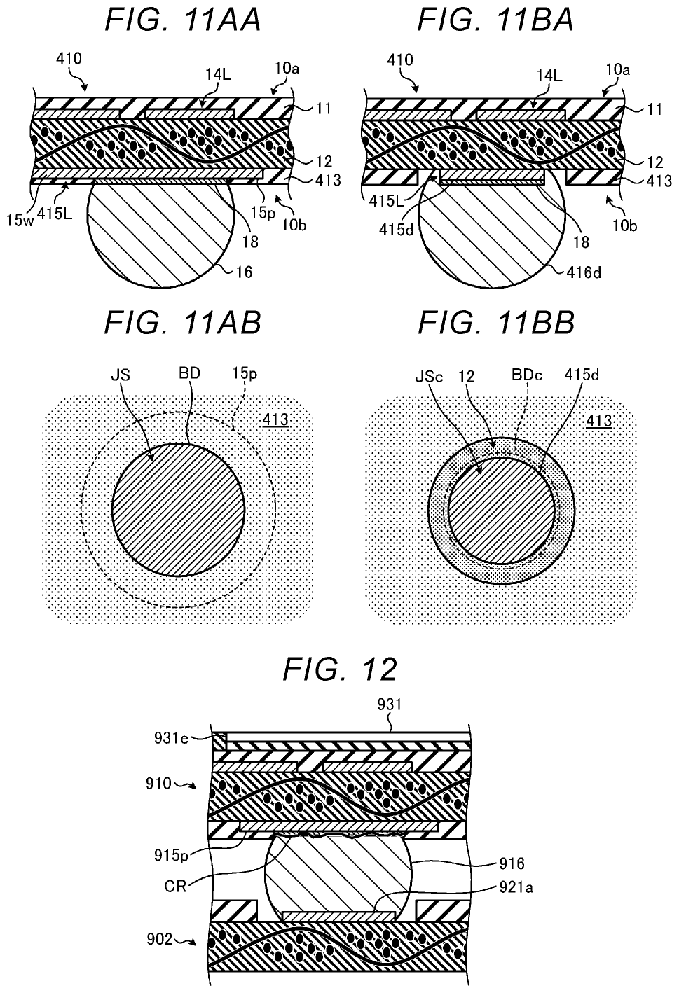

FIGS. 11AA to 11BB are diagrams illustrating an example of the detailed configuration of the electrode terminal 16 and a dummy terminal 416d provided in the semiconductor device according to the third embodiment.

FIG. 11AA is a cross-sectional view of the electrode terminal 16 in the state of being connected to a conductive layer 415L of a printed wiring substrate 410, and FIG. 11AB is a top view of the electrode pad 15p to which the electrode terminal 16 is bonded. In FIG. 11AB, the electrode pad 15p and a solder resist layer 413 are illustrated, and the electrode terminal 16 and the intervening layer 18 are omitted.

FIG. 11BA is a cross-sectional view of the dummy terminal 416d in a state of being connected to the conductive layer 415L of the printed wiring substrate 410, and FIG. 11BB is a top view of a dummy pad 415p to which the dummy terminal 416d is bonded. In FIG. 11BB, the dummy pad 415d and the solder resist layer 413 are illustrated, and the dummy terminal 416d and the intervening layer 18 are omitted.

As illustrated in FIGS. 11AA to 11BB, the semiconductor device of the third embodiment is provided on the printed wiring substrate 410 and the surface 10b side of the printed wiring substrate 410 and includes the conductive layer 415L covered with the solder resist layer 413, and the electrode terminal 16 and the dummy terminal 416d connected to the conductive layer 415L via the intervening layer 18. The conductive layer 415L includes the wiring 15w, the electrode pad 15p, and the dummy pad 415d.

Similarly to the first embodiment, the plurality of electrode terminals 16 are provided in the ball grid array and are bonded to the substantially circular electrode pad 15p formed integrally with the wiring 15w to be located in a grid shape in the rectangular region slightly larger than the mounting region of the semiconductor chip.

Further, similarly to the first embodiment described above, the plurality of dummy terminals 416d bonded to the plurality of dummy pads 415d are located in a grid shape at the four corners of the rectangular region where the ball grid array is located, which is outside the mounting region of the semiconductor chip.

As illustrated in FIGS. 11AA and 11AB, the electrode terminal 16 is bonded to the electrode pad 15p formed on the surface 10b of the printed wiring substrate 410 via the intervening layer 18. In the electrode pad 15p, the intervening layer 18 is formed, and the outer peripheral portion of the electrode pad 15p is covered with the solder resist layer 413 except for the bonding surface JS bonded to the electrode terminal 16. The electrode pad 15p is formed integrally with the wiring 15w covered with the solder resist layer 413.

As illustrated in FIG. 11AB, the electrode terminal 16 is bonded on a surface of the electrode pad 15p without protruding from the electrode pad 15p. That is, the bonding surface JS between the electrode terminal 16 and the electrode pad 15p has a diameter smaller than that of the electrode pad 15p and is located substantially concentrically with the electrode pad 15p at the position substantially matching the opening of the solder resist layer 413 and in a substantially central portion of the upper surface of the electrode pad 15p. Further, the boundary line of the bonding surface JS substantially overlaps the opening outer edge portion of the solder resist layer 413.

As described above, the relative sizes and positional relationships of the electrode terminal 16, the intervening layer 18, and the electrode pad 15p are the same as those in the above-described first embodiment.

As illustrated in FIGS. 11BA and 11BB, the dummy pad 415d is formed in a substantially circular shape on the surface 10b of the printed wiring substrate 410 without being connected to the wiring 15w or the like. The entire upper surface of the dummy pad 415d is covered with the intervening layer 18.

As described above, the dummy pad 415d is electrically in a floating state together with the dummy terminal 416d bonded to the dummy pad 415d and does not contribute to the electrical function of the semiconductor device of the third embodiment. However, as described above, the combination of some of the dummy pads 415d and the dummy terminals 416d may be used as, for example, test pins in shipping inspection of the semiconductor device.

As illustrated in FIG. 11BB, the solder resist layer 413 provided on the surface 10b of the printed wiring substrate 410 has the opening having a diameter larger than that of the dummy pad 415d in the region including the dummy pad 415d. That is, the entire upper surface of the dummy pad 415d and the core layer 12 around the dummy pad 415d are exposed from the opening of the solder resist layer 413.

Further, the dummy terminal 416d is bonded to the upper surface of the dummy pad 415d via the intervening layer 18 and is bonded to the entire side surface of the dummy pad 415d. That is, a boundary line BDc of a bonding surface JSc between the dummy terminal 416d and the dummy pad 415d has a diameter larger than that of the dummy pad 415d and a diameter smaller than that of the opening of the solder resist layer 413 and is located in a substantially central portion of the opening of the solder resist layer 413 substantially concentrically with the opening of the solder resist layer 413 and the dummy pad 415d.

As illustrated in FIGS. 11AB and 11BB, the dummy pad 415d has a diameter smaller than that of the electrode pad 15p. Further, the opening of the solder resist layer 413 is formed slightly larger than that in the electrode pad 15p in the dummy pad 415d. Furthermore, the area of the electrode pad 15p exposed from the opening of the solder resist layer 413 and provided with the intervening layer 18 also has a diameter larger than that of the dummy pad 415d.

The dummy terminal 416d protrudes from the upper surface of the dummy pad 415d which is smaller than the electrode pad 15p. Accordingly, the diameters and volumes of the dummy terminal 416d and the electrode terminal 16 are substantially the same.

The semiconductor device of the third embodiment can be manufactured by using the same technique as that of the first embodiment described above.

That is, the conductive layer 415L including the wiring 15w, the electrode pad 15p, the dummy pad 415d, and the like is formed on the surface 10b side of the printed wiring substrate 410. The material of the conductive layer 415L may be the same as or different from that of the conductive layer 14L. Further, the solder resist layer 413 having the opening in which a portion of the upper surface of the electrode pad 15p and the entire dummy pad 415d are exposed is formed.

Further, the intervening layer 18 is formed on the electrode pad 15p and the dummy pad 415d. At this time, by using an electrolytic plating process, the intervening layer 18 can be formed only on the portion of the electrode pad 15p exposed from the solder resist layer 413 in the electrode pad 15p. Further, in the dummy pad 415d, the intervening layer 18 is formed on the entire upper surface of the dummy pad 415d.

Further, soldering is performed on the electrode pad 15p and the dummy pad 415d via the intervening layer 18. At this time, for example, substantially the same amount of solder is used in the electrode pad 15p and the dummy pad 415d. Accordingly, the electrode terminal 16 is formed on the portion exposed from the solder resist layer 413 on the upper surface of the electrode pad 15p. Further, the dummy terminal 416d having the volume substantially equal to that of the electrode terminal 16 and covering the upper surface and the side surface of the dummy pad 415d is formed.

In this manner, the method in which the region to be soldered is determined by the opening of the solder resist layer 413 by exposing only a predetermined region on the upper surface of the electrode pad 15p is referred to as over-resist design, solder mask definition (SMD), or the like.

Further, the method in which the opening larger than the size of the dummy pad 415d is provided in the solder resist layer 413 and the region to be soldered is determined by the size of the dummy pad 415d is referred to as clearance resist design or non-solder mask definition (NSMD), or the like.

### Comparative Example

Next, in the semiconductor system of Comparative Example in which the semiconductor device is mounted on the mounting substrate 902, another thermal stress applied to the electrode terminal 916 of the semiconductor device will be described with reference to FIG. 12. FIG. 12 is a schematic diagram illustrating the thermal stress applied to the electrode terminal 916 of the semiconductor system according to Comparative Example.

As illustrated in FIG. 12, in some cases, in the electrode terminal 916 located in the mounting region of the semiconductor chip 931 mounted on the printed wiring substrate 910 in the vicinity of the end portion position 931e of the semiconductor chip 931, after the mounting TCT, the cracks CR may occur along the bonding surface with an electrode pad 915p of the printed wiring substrate 910.

According to the present inventors, it is found that such phenomenon gradually proceeds from the outside toward the inside of the mounting region of the semiconductor chip 931. That is, first, the breakage occurs between the dummy terminal and the dummy pad located outside the mounting region of the semiconductor chip 931, and gradually the breakage proceeds between the electrode terminal 916 and the electrode pad 915p in the vicinity of the mounting region and in the mounting region.

Further, it is found that, in one electrode terminal 916, similarly to the result of the thermal stress simulation of FIG. 5A described above, the cracks CR are likely to occur between the electrode terminal 916 and the electrode pad 915p and between the dummy terminal and the dummy pad on the side facing the outside of the mounting region of the semiconductor chip 931.

Herein, in a general semiconductor system such as the semiconductor system of Comparative Example, the electrode terminal 916 and the dummy terminal of the semiconductor device are connected to the electrode pad 915p and the dummy pad of the printed wiring substrate 910 by the SMD method. This is because, in the SMD method, the structure of the bonding portion between the electrode terminal 916 and the electrode pad 915p can be compactly formed, and the arrangement density can be improved. Further, in the SMD method, the bonding strength of the electrode pad 915p or the like to the printed wiring substrate 910 can be increased.

Meanwhile, the NSMD method is generally used for connecting the electrode terminal 916 and the dummy terminal to the electrode pad 921a of the mounting substrate 902. In the NSMD method, the bonding area between the dummy terminal and the electrode pad 921a is large, and the thermal stress at the electrode terminal 916 or the like is easily dispersed. For this reason, it is considered that the thermal stress applied to the electrode terminal 916 is concentrated on the electrode pad 915p side of the printed wiring substrate 910, and the cracks CR occur between the electrode terminal 916 and the electrode pad 915p.

In the semiconductor device of the third embodiment, the electrode terminal 16 is provided on a surface of the electrode pad 15p without protruding from the electrode pad 15p, and the dummy terminal 416d covers the entire side surface of the dummy pad 415d.

The bonding area between the dummy terminal 416d and the dummy pad 415d can be increased by configuring the dummy terminal 416d in this manner, and the thermal stress between the dummy terminal 416d and the dummy pad 415d and the thermal stress to the electrode pad of the mounting substrate can be balanced.

Accordingly, the occurrence of the cracks CR between the dummy terminal 416d and the dummy pad 415d can be reduced, and the influence of the thermal stress acting on the inner electrode terminal 16 and the electrode pad 15p can be reduced. Therefore, the influence of the stress applied to the electrode terminal 16 can be reduced.

Further, by connecting the electrode terminal 16 and the electrode pad 15p by the SMD method, the density and the degree of freedom of arrangement of the electrode pad 15p and the wiring 15w attached to the electrode pad 15p are improved. Further, the bonding strength of the electrode pad 15p to the printed wiring substrate 410 can be increased.

In the semiconductor device of the third embodiment, the dummy pad 415d is an electrode pad located at the position deviated from the mounting region of the semiconductor chip in the printed wiring substrate 410 and electrically in a floating state.

In this manner, by allowing the dummy pad 415d which does not contribute to an electrical function of the semiconductor device to have a function of dispersing the thermal stress, measures against the thermal stress can be taken without affecting the function of the semiconductor device. Further, even if the breakage occurs in the dummy pad 415d, the function of the semiconductor device can be maintained.

In the semiconductor device of the third embodiment, the dummy pad 415d has a diameter smaller than that of the electrode pad 15p. In this manner, by forming the NMSD type dummy pad 415d smaller than the MSD type electrode pad 15p, the dummy terminal 416d bonded to the dummy pad 415d and the electrode terminal 16 bonded to the electrode pad 15p can be allowed to have a substantially equal size.

Therefore, the area of the bonding surface JSc between the dummy pad 415d and the dummy terminal 416d can be prevented from increasing. Accordingly, the wiring capacitance can be prevented from increasing due to the capacitance effect with the adjacent conductive layer 14L due to the increase in the area of the bonding surface JSc.

### Modified Example 1

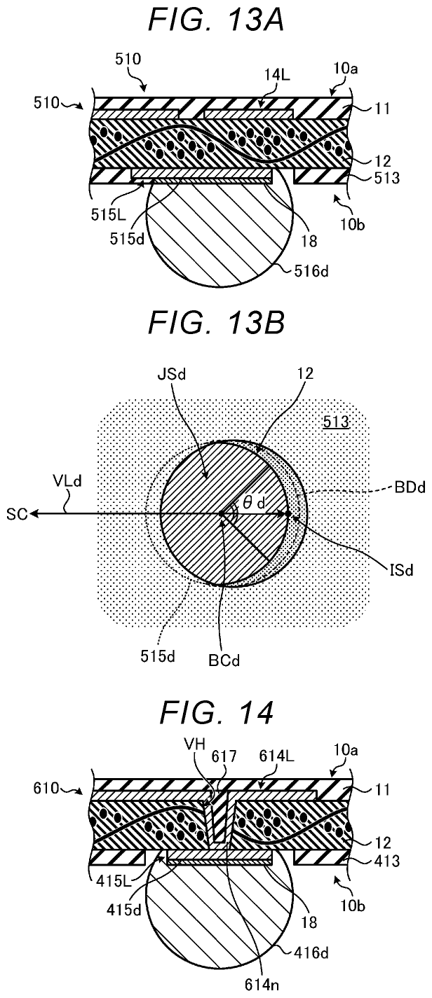

Next, a semiconductor device of Modified Example 1 of the third embodiment will be described with reference to FIGS. 13A and 13B. The semiconductor device of Modified Example 1 is different from that of the above-described third embodiment in that a dummy terminal 516d is eccentric with respect to a dummy pad 515d. In the following, in some cases, the same components as those in the third embodiment may be denoted by the same reference numerals, and the description thereof may be omitted.

FIGS. 13A and 13B are a diagrams illustrating an example of the detailed configuration of the dummy terminal 516d provided in the semiconductor device according to Modified Example 1 of the third embodiment.

FIG. 13A is a cross-sectional view of the dummy terminal 516d in a state of being connected to a conductive layer 515L of a printed wiring substrate 510, and FIG. 13B is a top view of the dummy pad 515d to which the dummy terminal 516d is bonded. In FIG. 13B, the dummy pad 515d and the solder resist layer 513 are illustrated, and the dummy terminal 516d and the intervening layer 18 are omitted.

As illustrated in FIGS. 13A and 13B, for example, the dummy pad 515d has a diameter larger than that of the dummy pad 415d of the third embodiment described above, and one end portion thereof is covered with the solder resist layer 513. One end portion of the dummy pad 515d covered with the solder resist layer 513 is the side facing the inner side of the mounting region of the semiconductor chip.

The intervening layer 18 is provided on the upper surface of the dummy pad 515d exposed from the solder resist layer 513. Further, the dummy terminal 516d is bonded to the upper surface of the dummy pad 515d via the intervening layer 18 and covers the side surface of the dummy terminal 516d on the side exposed from the solder resist layer 513. That is, the dummy terminal 516d covers the side surface of the dummy pad 515d on the side facing the outside of the mounting region of the semiconductor chip.

Accordingly, a bonding surface JSd between the dummy terminal 516d and the dummy pad 515d is in the state of being eccentric toward the outside of the mounting region of the semiconductor chip with respect to the dummy pad 515d having a substantially circular shape.

For this reason, a boundary line BDd of the bonding surface JSd is located at the position substantially matching with the outer edge portion of the opening of the solder resist layer 513 on the side facing the inner side of the mounting region of the semiconductor chip. Further, on the side facing the outside of the mounting region of the semiconductor chip, the boundary line BDd of the bonding surface JSd is located on the core layer 12 exposed from the opening of the solder resist layer 513 beyond the end portion of the dummy pad 515d. This point will be described in more detail below.

In FIG. 13B, when viewed from the surface 10b side of the printed wiring substrate 510, a virtual line VLd connecting the center point SC of the semiconductor chip mounted on the printed wiring substrate 510 and a center point BCd of the dummy pad 515d are illustrated.

As illustrated in FIG. 13B, the dummy terminal 516d covers the side surface of the dummy pad 515d over a predetermined range of the outer edge portion of the dummy pad 515d including an intersection ISd between the outer edge portion of the dummy pad 515d on the side facing the outside of the mounting region of the semiconductor chip and the virtual line VLd extending toward the outside of the mounting region of the semiconductor chip.

More specifically, the dummy terminal 516d covers the side surface of the dummy pad 515d included in a range of a predetermined angle θ from the center point BCd of the dummy pad 515d toward the outside of the mounting region. The predetermined range on the side surface of the dummy pad 515d covered with the dummy terminal 516d is a range in which the significant stress concentration is observed in the dummy terminal 516d and is, for example, a range in which the angle θ is 90° or more and less than 180°.

The semiconductor device of Modified Example 1 can also be manufactured by using the same technique as that of the first embodiment described above.

That is, the conductive layer 515L including the dummy pad 515d and the like is formed on the surface 10b side of the printed wiring substrate 510. The material of the conductive layer 515L may be the same as or different from that of the conductive layer 14L. Further, the solder resist layer 513 having the opening that covers one end portion of the dummy pad 515d and exposes the other end portion is formed.

Further, the intervening layer 18 is formed on the dummy pad 515d. At this time, by using the electrolytic plating process, the intervening layer 18 is formed only on the portion exposed from the solder resist layer 513 on the side of the dummy pad 515d covered with the solder resist layer 513. Further, the intervening layer 18 is formed up to the end portion of the dummy pad 515d on the side where the end portion of the dummy pad 515d is exposed.

Further, soldering is performed on the dummy pad 515d via the intervening layer 18. Accordingly, the dummy terminal 516d that covers the upper surface of the dummy pad 515d exposed from the solder resist layer 513 and the side surface on the side where the end portion is exposed is formed.

As described above, in the method for manufacturing the semiconductor device of Modified Example 1, it can be said that the connection method of the dummy terminal 516d is an SMD method on the side of the dummy pad 515d which is covered with the solder resist layer 513 and an NSMD method on the side where the end portion of the dummy pad 515d is exposed.

In the semiconductor device of Modified Example 1, the dummy terminal 516d covers the side surface of the dummy pad 515d on the side facing the outside of the mounting region of the semiconductor chip. Further, the range in which the dummy terminal 516d covers the side surface of the dummy pad 515d is a range of 90° or more and less than 180° from the center point BCd of the dummy pad 515d toward the outside of the mounting region of the semiconductor chip.

As described above, the occurrence of the cracks CR can be reduced by covering the side surface of the dummy pad 515d with the dummy terminal 516d only in the portion where the thermal stress is likely to be concentrated.

In the semiconductor device of Modified Example 1, the solder resist layer 513 covers the end portion of the dummy pad 515d on the side facing the inner side of the mounting region of the semiconductor chip. Accordingly, the bonding strength of the dummy pad 515d to the printed wiring substrate 510 can be increased, and the peeling of the dummy pad 515d can be reduced as compared with the case where the dummy pad 515d is connected by the NSMD method.

With the semiconductor device of Modified Example 1, in addition to this, the same effects as those of the semiconductor device of the third embodiment described above are obtained.

### Modified Example 2

Next, a semiconductor device of Modified Example 2 of the third embodiment will be described with reference to FIG. 14. The semiconductor device of Modified Example 2 is different from that of the above-described third embodiment in that the semiconductor device has a via hole VH penetrating a printed wiring substrate 610 in addition to the configuration of the third embodiment. In the following, in some cases, the same components as those in the third embodiment may be denoted by the same reference numerals, and the description thereof may be omitted.

FIG. 14 is a cross-sectional view illustrating an example of the detailed configuration of the dummy terminal 416d provided in the semiconductor device according to Modified Example 2 of the third embodiment.

As illustrated in FIG. 14, the semiconductor device of Modified Example 2 includes a printed wiring substrate 610 provided with a via hole VH, a conductive layer 614L, and a filler 617.

The via hole VH is provided on the surface 10a side overlapping the dummy pad 415d provided on the surface 10b side of the printed wiring substrate 610. Specifically, the via hole VH penetrates the core layer 12 of the printed wiring substrate 610 and reaches the surface of the dummy pad 415d in contact with the core layer 12.

The conductive layer 614L includes a liner layer 614n provided in the via hole VH and is formed on the surface 10a side of the printed wiring substrate 610. The liner layer 614n is formed integrally with the conductive layer 614L provided on the upper surface of the core layer 12 on the surface 10a side and covers the side wall and the bottom surface of the via hole VH. The liner layer 614n on the bottom surface of the via hole VH is connected to the surface of the dummy pad 415d in contact with the core layer 12.

The filler 617 is buried further inside the liner layer 614n in the via hole VH. The filler 617 is, for example, a metal, a resin, or the like and preferably contains a material having an elasticity higher than that of the core layer 12, that is, a material harder than the core layer 12.

The semiconductor device of Modified Example 2 can also be manufactured by using the same technique as that of the first embodiment described above.

That is, on the surface 10b side of the printed wiring substrate 610 by the above-described method, the conductive layer 415L including the dummy pad 415d and the like is formed, the solder resist layer 413 covering a portion of the conductive layer 415L is formed, and the intervening layer 18 is formed on the upper surface of the conductive layer 415L exposed from the solder resist layer 413. After that, the electrode terminal 16, the dummy terminal 416d and the like are formed at predetermined timings.

Meanwhile, the via hole VH penetrating the core layer 12 is formed on the surface 10a side of the printed wiring substrate 610. The via hole VH can be formed by laser-processing or drilling the core layer 12.

Further, in parallel with the above-described process on the surface 10b side, the conductive layer 614L is formed on the surface 10a side of the printed wiring substrate 610 by the Cu plating process or the like. At this time, the liner layer 614n that covers the side surface and the bottom surface of the via hole VH and is connected to the dummy pad 415d is also formed.

Further, the inside of the via hole VH is filled with the filler 617. When metal is used for the filler 617, the via hole VH may be filled with metal plating by the plating process or the like. After that, the solder resist layer 11 that covers at least the conductive layer 614L is formed.

In the semiconductor device of Modified Example 2, the via hole VH which penetrates the printed wiring substrate 610 from the surface 10a side toward the surface 10b side and in which the side wall and the bottom surface are covered with the liner layer 614n is provided at the position overlapping the dummy pad 415d. Further, the liner layer 614n is connected to the dummy pad 415d.

Accordingly, even with the dummy pad 415d connected by the NSMD method, the bonding strength to the printed wiring substrate 610 can be increased, and the peeling of the dummy pad 415d can be reduced.

With the semiconductor device of Modified Example 2, in addition to this, the same effects as those of the semiconductor device of the third embodiment described above are obtained.

It is noted that, in the above-mentioned Modified Example 2, the above-described configuration is applied to the dummy pad 415d and the dummy terminal 416d of the third embodiment. However, the configuration of the via hole VH having the liner layer 614n connected to the dummy pad 515d may be applied to the dummy pad 515d and the dummy terminal 516d of Modified Example 1.

Further, in the above-described third embodiment and Modified Examples 1 and 2, the electrode terminal 16 and the electrode pad 15p having a very general configuration are used. However, the configurations such as the dummy pads 415d and 515d, the dummy terminals 416d and 516d, and the via hole VH of the third embodiment and Modified Examples 1 and 2 may be used in combination with the above-described first and second embodiments and Modified Examples 1 and 2.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a printed wiring substrate;
a semiconductor chip mounted on a first surface of the printed wiring substrate;
a sealing resin sealing the semiconductor chip on the first surface;
an electrode pad disposed on a second surface on a side of the printed wiring substrate opposite to the first surface;
an electrode terminal connected to the electrode pad and protruding from the second surface; and
a metal layer disposed either on a surface of the electrode pad on the electrode terminal side or disposed on the side opposite to the electrode terminal, such that the metal layer straddles a boundary line of the bonding surface between the electrode terminal and the electrode pad which is at least a boundary line on a side facing an outside of a mounting region of the semiconductor chip.

2. The semiconductor device according to claim 1, wherein the metal layer is a thickened portion of the electrode pad and the metal layer is disposed over the entire boundary line.

3. The semiconductor device according to claim 2, wherein the metal layer is also disposed in the boundary line, and the metal layer covers the entire surface overlapping the bonding surface.

4. The semiconductor device according to claim 1,
wherein the metal layer is an intervening layer interposed between the electrode terminal and the electrode pad, and
wherein the electrode terminal and the electrode pad are bonded via the metal layer.

5. The semiconductor device according to claim 4, further comprising a grid array, the grid array having a plurality of electrode terminals located in a grid shape, the plurality of electrode terminals including the electrode terminal at a position overlapping the mounting region on the printed wiring substrate,
wherein the electrode terminal is located at a position overlapping an outer edge portion of the mounting region on the printed wiring substrate, or located at an outermost peripheral portion in the mounting region among the plurality of electrode terminals.

6. The semiconductor device according to claim 4, wherein the metal layer covers the entire bonding surface and extends beyond the boundary line toward the outside of the mounting region.

7. The semiconductor device according to claim 6, wherein, when viewed from the second surface side of the printed wiring substrate, the metal layer extends beyond the boundary line over a predetermined range of the boundary line, the predetermined range including an intersection between a virtual line connecting a center point of the semiconductor chip and a center point of the electrode terminal, and extending toward the outside of the mounting region and the boundary line on the side facing the outside of the mounting region.

8. The semiconductor device according to claim 1, further comprising:
a dummy pad disposed on the second surface side of the printed wiring substrate; and
a dummy terminal connected to the dummy pad and protruding from the second surface,
wherein the dummy terminal covers at least the side surface of the dummy pad on the side facing the outside of the mounting region.

9. A semiconductor device comprising:
a printed wiring substrate;
a semiconductor chip mounted on a first surface of the printed wiring substrate;
a sealing resin sealing the semiconductor chip on the first surface of the printed wiring substrate;
an electrode pad disposed on a second surface side opposite to the first surface of the printed wiring substrate;
a dummy pad disposed on the second surface side of the printed wiring substrate;
an electrode terminal connected to the electrode pad and protruding from the second surface; and
a dummy terminal connected to the dummy pad and protruding from the second surface,
wherein the electrode terminal is disposed on a surface of the electrode pad without protruding from the electrode pad, and
wherein the dummy terminal covers a side surface of the dummy pad on a side facing an outside of a mounting region of the semiconductor chip.

10. The semiconductor device according to claim 9,
wherein the printed wiring substrate has a via hole penetrating the printed wiring substrate from the first surface side toward the second surface side, and has a side wall and a bottom surface covered with a liner layer at a position overlapping the dummy pad, and
wherein the liner layer is connected to the dummy pad.

11. The semiconductor device according to claim 1, wherein the semiconductor device includes a NAND memory.

12. The semiconductor device according to claim 1, wherein the semiconductor device includes at one of a memory or a memory controller.

13. The semiconductor device according to claim 1, further including a plurality of stacked semiconductor chips including the semiconductor chip.

14. The semiconductor device according to claim 13, further including bonding wires electrically connecting at least some of the plurality of stacked semiconductor chips to the first surface.

15. The semiconductor device according to claim 1, wherein the metal layer includes a plating layer.

16. The semiconductor device according to claim 4, wherein the intervening layer includes a plating layer.

17. The semiconductor device according to claim 1, wherein the mounting region has a substantially rectangular shape.

18. The semiconductor device according to claim 1, wherein the electrode terminal includes a solder bump or a solder ball.

19. The semiconductor device according to claim 9, wherein the dummy terminal includes a solder bump or a solder ball.
